(19) United States
(12) Patent Application Publication
(10) Pub. No.: US 2006/0238989 A1
(43) Pub. Date: Oct. 26, 2006

(54) Bonding and protective method and apparatus for RFID strap

(75) Inventors: Kevin Stone Manes, St. Charles, MO (US); Gregory Neal Wells, St. Charles, MO (US); David Anthony Kuhn, St. Charles, MO (US); Martin Alan Ross, Wildwood, MO (US)

Correspondence Address: FOLEY AND LARDNER LLP;SUITE 500, 3000 K STREET NW, WASHINGTON, DC, 20007, US

(73) Assignee: Delaware Capital Formation, Inc.

(21) Appl. No.: 11/113,319

(22) Filed: Apr. 25, 2005

(51) Int. Cl. H05K 7/06

(52) U.S. Cl. 361/760; 361/782; 340/572.8

(57) ABSTRACT

A method and apparatus for bonding an RFID strap to a substrate, one embodiment of the method comprising: applying a bonding tape with an adhesive on at least one side to an RFID strap so that the RFID strap is mechanically bonded to the bonding tape to result in a laminated bonding tape and RFID strap, wherein the strap includes an electrical chip and strap leads, and wherein the strap does not include an antenna; cutting the laminated bonding tape and RFID strap into a piece so that the bonding tape extends beyond opposite ends of the RFID strap for the piece; and mechanically bonding the bonding tape of the piece to the substrate in an orientation so that the RFID strap leads on the piece electrically couple to an antenna.

### BACKGROUND OF THE INVENTION

RFID tags and labels have a combination of an antenna and analog and/or digital electronics, which may include for example communications electronics, data memory, and control logic. RFID tags and labels are widely used to associate an object with an identification code. For example, RFID tags are used in conjunction with security-locks in cars, for access control to buildings, and for tracking inventory and parcels.

RFID tags and labels include active tags, which include a power source, and passive tags and labels, which do not. In the case of passive tags, in order to retrieve the information from the chip, a “base station” or “reader” sends an excitation signal to the RFID tag or label. The excitation signal energizes the tag or label, and the RFID circuitry transmits the stored information back to the reader. The “reader” receives and decodes the information from the RFID tag. In general, RFID tags can retain and transmit enough information to uniquely identify individuals, packages, inventory and the like. RFID tags and labels also can be characterized as those to which information is written only once (although the information may be read repeatedly), and those to which information may be written during use.

Straps comprise RFID chips containing the electronics for the tag identity and one or more strap leads to connect to an antenna. A straps is applied to a separate RFID antenna with a conductive adhesive that is intended to provide both mechanical and electrical continuity. However, problems have arisen in holding the strap on the antenna, particularly during thermal curing cycles.

### SUMMARY OF THE INVENTION

In one embodiment, a method is provided for bonding an RFID strap to a substrate, comprising: applying a bonding tape with an adhesive on at least one side to an RFID strap so that the RFID strap is mechanically bonded to the bonding tape to result in a laminated bonding tape and RFID strap, wherein the strap includes an electrical chip and strap leads, and wherein the strap does not include an antenna; cutting the laminated bonding tape and RFID strap into a piece so that the bonding tape extends beyond opposite ends of the RFID strap for the piece; and mechanically bonding the bonding tape of the piece to the substrate in an orientation so that the RFID strap leads on the piece electrically couple to an antenna.

In a further embodiment, an RFID label is provided, comprising: a substrate; an antenna disposed on the substrate; a strap discrete from the antenna, the strap including an RFID chip and strap leads, wherein the strap leads are electrically coupled to the antenna; and a bonding tape disposed to extend across opposite ends of the RFID strap and to bond to a portion of the substrate.

### BRIEF DESCRIPTION OF THE DRAWINGS

FIG. 1 is a side view of one embodiment of a strap in relation to a substrate having an antenna formed thereon.

FIG. 2 is a top view of one embodiment of the present invention.

FIG. 3 is a schematic diagram illustrating an embodiment of a method of the present invention.

FIG. 4 is a schematic diagram illustrating a further aspect of a method of the present invention.

### DETAILED DESCRIPTION OF THE PREFERRED EMBODIMENTS

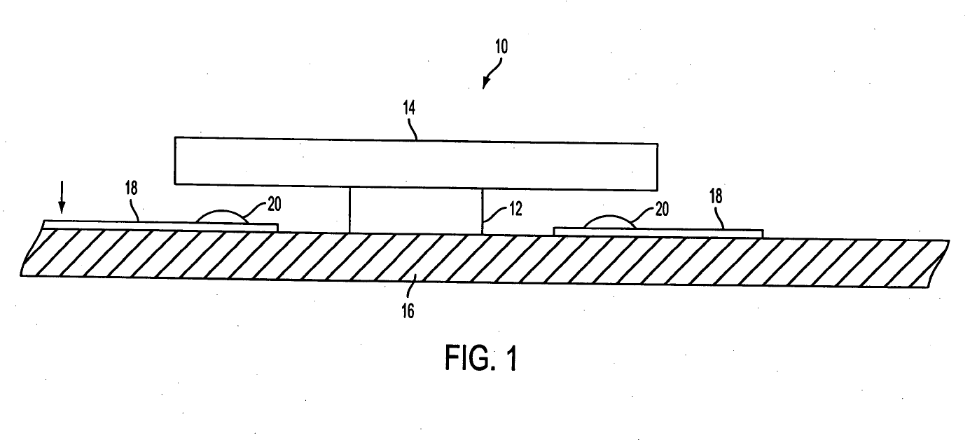

Referring to FIG. 1, one embodiment of a strap 10 in relation to a substrate 16 having an antenna 18 pre-formed on the substrate is shown that may be used in an embodiment of the invention. The strap 10 includes an RFID chip 12 having chip contacts (not shown) that are electrically coupled to strap leads 14. The RFID chip 12 may be any of a variety of suitable electronic components for electrically coupling to and interacting with the antenna 18, for example to receive and/or to send signals.

The strap leads 14 may be made out of an electrically conducting material, such as metal foil for example. In some embodiments, the strap leads 14 may include an electrically insulating material along selected portions of the conducting material. Alternatively, the strap leads 14 may include a dielectric material with conductive layers on one or both sides.

The substrate 16 may be any of a variety of suitable materials. Suitable materials for the substrate 16 include materials that are flexible, and are suitable for use in roll-to-roll processes. The substrate 16 may be a piece of material that has been separated from a webstock or sheetstock. Examples of suitable materials for the substrate 104 include, but are not limited to, high Tg polycarbonate, poly(ethylene terephthalate), polyarylate, polysulfone, a norbornene copolymer, poly phenylsulfone, polyetherimide, polyethylenenaphthalate (PEN), polyethersulfone (PES), polycarbonate (PC), a phenolic resin, polyester, polyimide, polyetherester, polyetheramide, cellulose acetate, aliphatic polyurethanes, polyacrylonitrile, polytrifluoroethylenes, polyvinylidene fluorides, HDPEs, poly(methyl methacrylates), a cyclic or acyclic polyolefin, or paper.

The antenna 18 any of a variety of suitable configurations. The antenna 18 may be made of a conductive material, such as a metallic material. The antenna 18 may be formed on the substrate 16 by any of a variety of methods. For example, the antenna 18 may be formed from a conductive ink that is printed or otherwise deposited on the substrate 16. Alternatively, the antenna 18 may be formed from metal deposited on the substrate 16 by any of a variety of suitable, known deposition methods, such as vapor deposition. As a further alternative, the antenna 18 may be part of a web of antenna material that is adhered to the substrate 16 by suitable means, for example, by use of a suitable adhesive in a lamination process. Such a web comprising a plurality of antennas may be made from, for example, copper, silver, aluminum or other thin conductive material (such as etched or hot-stamped metal foil, conductive ink, sputtered metal, etc.). The web of antennas may be on a film, coated paper, laminations of film and paper, or other suitable substrate. As yet another alternative, the antenna 18 may be formed by selective removal of metal from a metal layer, for example, using known lithography processes. It will be appreciated that other suitable means, for example, electroplating, may be used to form the antenna 18 om the substrate 16.

The strap leads 14 are electrically coupled to the antenna 18 via an electrically-conductive material 20. In the prior art, the material 20 was an adhesive that is electrically conductive and also provides a mechanical bond. Adhesives that provide both a desired electrical connection and mechanical properties require a thermal cure process to achieve their final adhesive strength. Prior to such thermal curing, the uncured (green) mechanical strength of the adhesive must be sufficient to hold the strap lead 14 onto the antenna 18.

There is a physical offset of the electrical pad of the strap lead 14 from the material 20, as can be seen in the drawing. In one process, the soft rubber of an impression role is used to press the strap leads 14 into electrical contact with the conductive adhesive 20 on the antenna 18. Applicants have recognized that because there is some rigidity to the strap leads 14, and because of a relatively low uncured strength of the conductive adhesive 20, the strap leads 14 sometimes do not stay in contact with the conductive adhesive 20 through the curing cycle. Example dimensions for the length of the strap 10 is approximately ⅜ inches, with a strap lead thickness of 0.003 inches. The physical offset between the bottom of the strap leads 14 and the antenna 18 would on the order of 0.003 inches. Note that the dimensions of the strap and the antenna are not limiting on the invention.

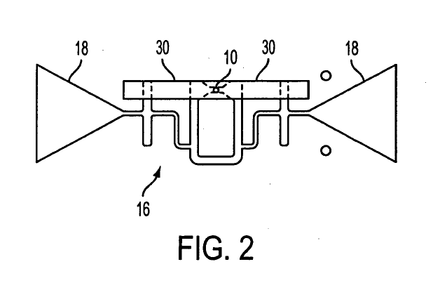

Referring now to FIG. 2, an embodiment of the present invention is shown. Shown disposed on the substrate 16 is an antenna 18 with a strap 10 disposed thereon. A bonding tape 30 has been added to cause the strap to stay in contact with the material 20. The bonding tape 30 may be made of any convenient tape such as, for example, acytate, polypropylene, and polyester. In one embodiment the bonding tape 30 is of an elastic material. The bonding tape 30 may be self-winding or may be a linered tape with a silicon release layer.

The bonding tape 30 provides the necessary mechanical bonding strength to hold the strap leads 14 in position in contact with the antenna 18. Thus, with the use of the bonding tape 30, the material 20 may be chosen with minimal mechanical bonding strength in either its uncured or its cured state. Thus, in one embodiment the material 20 may be chosen with a focus on its electrical continuity properties without any mechanical bonding strength. Such a material 20 may provide superior electrical performance as compared to a material that is required to provide both good electrical continuity and substantial mechanical bonding strength, and such material may not require a curing step and may also be less expensive. Thus, in one embodiment, thermal curing may be eliminated based on the choice of the material 20. Where a material 20 is chosen that requires some curing to realize its adhesive and or electrical properties, then in one embodiment it may be advantageous to have a material with good electrical conductivity and a minimum uncured (green) adhesive strength that approximates the weight of the strap 10 divided by the area of the strap. For example, for a strap weighing 5 milligrams and having an area of 36 square millimeters, it would be advantageous to have an uncured adhesive strength of approximately 100 micrograms per square millimeter to provide a minimum force to hold the strap in place during processing. Alternatively, a design may be utilized with no bond formed between the strap and the antenna. In some embodiments the material 20 may even be eliminated.

Alternatively, if the material 20 requires a thermal curing cycle to attain its desired mechanical or electrical performance, then the bonding tape 30 operates to hold the strap leads 14 in place in contact via the material 20 with the antenna 18 during the curing cycle.

The bonding tape 30 also provides physical protection to the strap 10 on the backside of a label construction when a release liner for the label is removed. The addition of the bonding tape 30 provides a protective barrier for the strap 10.

Additionally, in one embodiment the mechanical bond provided by the bonding tape 30 is resilient to vibration and mechanical stress. Thus the use of the bonding tape 30 is superior to a brittle adhesive that once fractured, incurs permanent failure. Note that with the bonding tape 30 in place, it is possible that an electrical connection between the strap leads and the antenna may be broken momentarily due to an instantaneous stress, but will self-repair when the stress is removed.

An additional benefit of one embodiment of the invention that will be discussed in more detail in relation to embodiments of a method of the invention is that the strap and bonding tape piece provides a larger footprint as compared to the strap alone. This larger footprint results in an increased vacuum on any vacuum roll holding the strap and bonding tape piece, thereby allowing a greater spacing of vacuum nozzles and/or a lower vacuum for the vacuum roll.

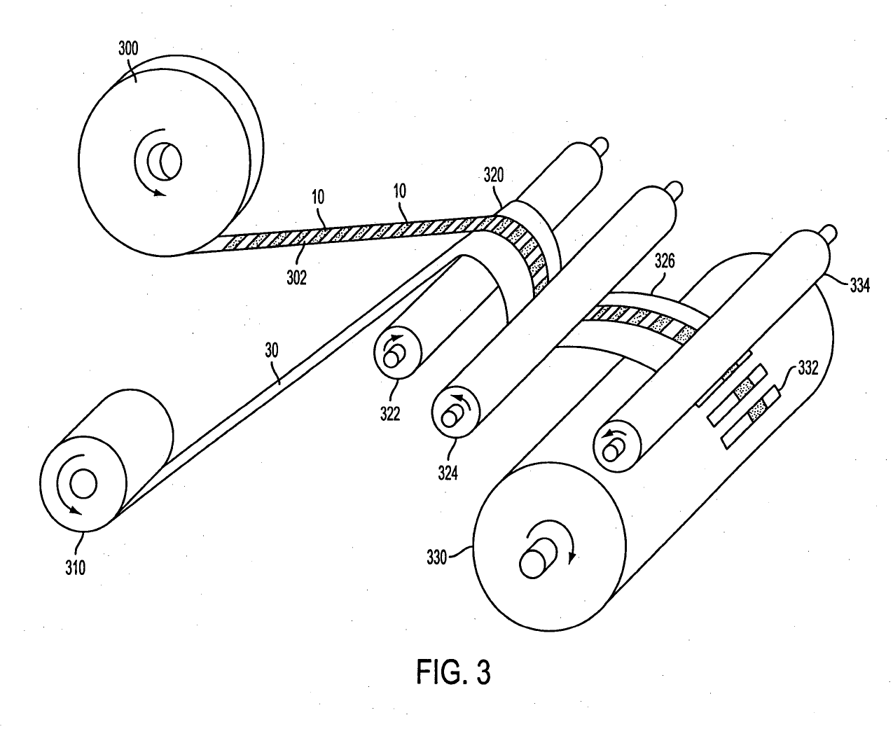

Referring now to FIG. 3, there is a schematic diagram illustrating an embodiment of a method of the present invention. A strap reel 300 is provided comprising a web 302 with a plurality of straps 10 disposed in-line thereon. Also provided is a reel 310 of bonding tape 30. The web 302 with the straps 10 is laminated to the bonding tape web 30 as both webs meet at a tangent 320 on a roll 322, and are passed by a second roll 324.

The resulting web 326 comprising the web 302 with the straps laminated to the bonding tape 30 proceeds to a tangent on a vacuum roll 330. The web 326 is then cut into individual pieces 332 as it is passed between the vacuum roll 330 and a knife roll 334. Note that the particular roll configuration is not limiting on the invention. Additionally, the means of cutting the web 326 into the pieces 332 is not limiting on the invention. For example, the cutting step could be performed by a laser. The vacuum roll 330, in one embodiment, may be implemented by a series of holes and may have a vacuum pulled from the center of the roll. The pieces 332 that result from the cutting step are disposed over the different respective holes in the vacuum roll 330 and held thereon by the pull of the vacuum drawn from the center of the roll 330.

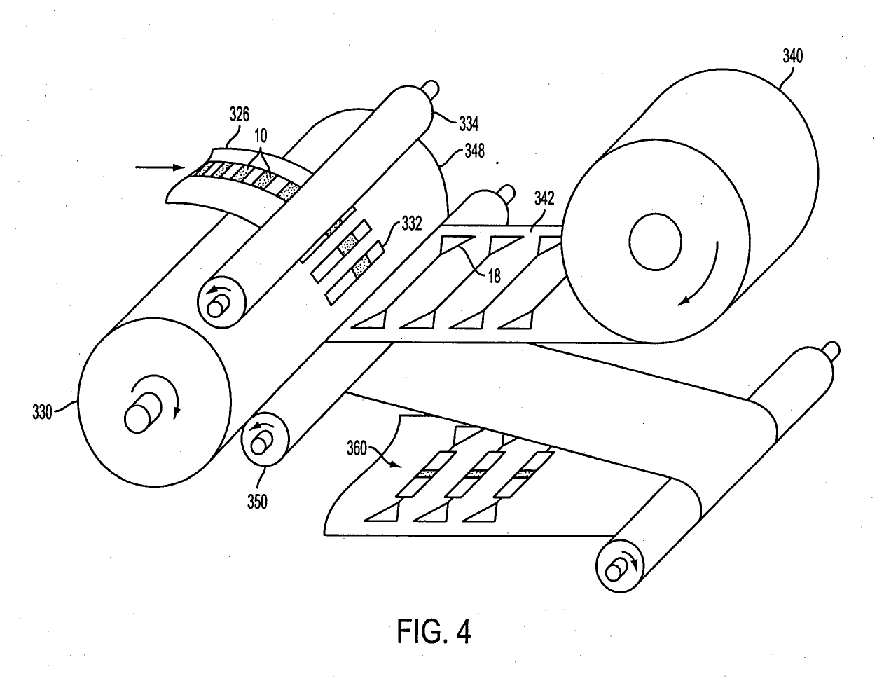

Referring now to FIG. 4, there is shown a portion of the method wherein the pieces 332 are adhered to the antennas 18. In the embodiment shown, a reel 340 comprises a plurality of antennas 18 disposed in-line on a web 342. In the embodiment, the individual pieces 332 held by the vacuum roll 330 meet and are pressed against and attached to the antennas 18 on the web 342 at a tangent line 348 between the vacuum roll 330 and an impression roll 350. Each individual antenna 18 on the web 342 is shown with one of the pieces 332 attached thereto by the bonding tape 30 at 360.

Accordingly, in one embodiment of the invention, a method is provided for bonding an RFID strap 10 to a substrate, comprising: applying a bonding tape 30 with an adhesive on at least one side to an RFID strap 10 so that the RFID strap is mechanically bonded to the bonding tape 30 to result in a laminated bonding tape and RFID strap, wherein the strap includes an electrical chip 12 and strap leads 14, and wherein the strap 10 does not include an antenna. The method further comprises cutting the laminated bonding tape and RFID strap into a piece 332 so that the bonding tape extends beyond opposite ends of the RFID strap 10 for the piece 332. The method further comprises mechanically bonding the bonding tape of the piece 332 to the substrate in an orientation so that the RFID strap leads 14 on the piece 332 electrically couple to an antenna 18.

As noted previously, an additional benefit arising from this method is that the strap and bonding tape piece provides a larger footprint as compared to the strap alone. This larger footprint results in an increased vacuum on any vacuum roll holding the strap and bonding tape piece, thereby allowing a greater spacing of vacuum nozzles and/or a lower vacuum for the vacuum roll.

The foregoing description of a preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined the claims appended hereto, and their equivalents.

What is claimed is:

1. A method for bonding an RFID strap to a substrate, comprising:
applying a bonding tape with an adhesive on at least one side to an RFID strap so that the RFID strap is mechanically bonded to the bonding tape to result in a laminated bonding tape and RFID strap, wherein the strap includes an electrical chip and strap leads, and wherein the strap does not include an antenna;
cutting the laminated bonding tape and RFID strap into a piece so that the bonding tape extends beyond opposite ends of the RFID strap for the piece; and
mechanically bonding the bonding tape of the piece to the substrate in an orientation so that the RFID strap leads on the piece electrically couple to an antenna.

2. The method as defined in claim 1,
wherein there are a plurality of straps disposed in a line on a web;
wherein the cutting step comprises cutting the laminated bonding tape and the plurality of RFID straps into a plurality of pieces, and
wherein the mechanical bonding step comprises mechanically bonding the bonding tape of each different piece to a different in-line location on the substrate in an orientation so that the lead lines of the RFID strap on each different piece electrically couples to a different antenna.

3. The method as defined in claim 1, further comprising bonding each of the strap leads to a different portion of the antenna.

4. The method as defined in claim 2, further comprising bonding each of the strap leads to a different portion of the antenna with an adhesive that has electrical conductivity and that has a tensile strength that is reduced relative to adhesive strength of an adhesive used when there is no other mechanical support for the bond.

5. The method as defined in claim 2, wherein the applying step comprises laminating a web for the bonding tape and a web holding the plurality of in-line RFID straps at a tangent line of a roll.

6. The method as defined in claim 1, wherein the cutting step is performed by a knife roll.

7. The method as defined in claim 2,
wherein the cutting step further comprises holding the individual pieces on a roll after the cutting step; and
wherein the mechanically bonding the bonding tape to the substrate step comprises laminating each different individual piece held on the roll to a different in-line location on a substrate web at a junction between the roll and a cylinder.

8. The method as defined in claim 7, wherein the roll is a vacuum roll with holes therein, and wherein the bonding tape functions to increase a footprint of the strap over at least one of the holes in the roll thereby increasing the vacuum hold on the strap by the roll.

9. The method as defined in claim 1, wherein the bonding tape extends across a long axis of the strap.

10. The method as defined in claim 1, wherein the bonding tape is made of an elastic material.

11. The method as defined in claim 1, further comprising prior to the mechanically bonding step forming a plurality of antennas in a line on the substrate.

12. The method as defined in claim 1, wherein no adhesive is used for bonding of the strap leads to the antenna.

13. The method as defined in claim 1, wherein the strap leads are not bonded to the antenna.

14. An RFID label, comprising:
a substrate;
an antenna disposed on the substrate;
a strap that is discrete from the antenna, the strap including an RFID chip and strap leads, wherein the strap leads are electrically coupled to the antenna; and
a bonding tape disposed to extend across opposite ends of the RFID strap and to bond to a portion of the substrate.

15. The label as defined in claim 14, wherein each of the strap leads is bonded to a different portion of the antenna using an adhesive that has electrical conductivity and a tensile strength that is reduced relative to adhesive strength of an adhesive used when no other mechanical support is provided for the strap.

16. The RFID label as defined in claim 14, wherein the bonding tape extends across a long axis of the strap.

17. The RFID label as defined in claim 14, wherein the bonding tape comprises an elastic material.

18. The RFID label as defined in claim 14, wherein no adhesive is used for bonding of the strap leads to the antenna.

19. The RFID label as defined in claim 14, wherein the strap leads are not bonded to the antenna.
